(19) United States
(12) Patent Application Publication
(10) Pub. No.: US 2017/0213807 A1
(43) Pub. Date: Jul. 27, 2017

(54) TUNGSTEN LAYER PASSIVATION PROCESS AND DIRECT BONDING PROCESS

(71) Applicant: COMMISSARIAT A L'ENERGIE ATOMIQUE ET AUX ENERGIES ALTERNATIVES, Paris (FR)

(72) Inventors: Lamine BENAISSA, Massy (FR); Paul GONDCHARTON, Grenoble (FR); Bruno IMBERT, Grenoble (FR)

(73) Assignee: COMMISSARIAT A L'ENERGIE ATOMIQUE ET AUX ENERGIES ALTERNATIVES, Paris (FR)

(21) Appl. No.: 15/321,418

(22) PCT Filed: Jun. 22, 2015
(86) PCT No.: PCT/EP2015/063932

§ 371 Date: Dec. 22, 2016

(30) Foreign Application Priority Data
Jun. 24, 2014 (FR) 14 55848

(51) Int. Cl. H01L 23/00; C23C 14/00; C23C 14/16; C23C 14/34; H01L 25/00; H01L 21/18; H01L 21/285; H01L 21/768; H01L 23/532; C22F 1/18; C23C 14/58

(52) U.S. Cl. CPC H01L 24/83; C22F 1/18; C23C 14/0036; C23C 14/165; C23C 14/3414; C23C 14/5806; H01L 21/187; H01L 21/2855; H01L 21/76834; H01L 23/53266; H01L 25/50; H01L 21/76898; H01L 2224/05184

(57) ABSTRACT

A method for forming and passivating a tungsten layer, including: a) depositing, by PVD deposition, a tungsten layer on a substrate; and b) depositing by PVD deposition, a tungsten oxide passivation layer on the tungsten layer, by reactive sputtering in a plasma containing dioxygen, the tungsten oxide layer as deposited being amorphous and having a resistivity of between 5×10−2 and 5×10−3 O·cm, the substrate being kept in an inert atmosphere between a) and b).

### TECHNICAL FIELD

The present invention relates to a method for passivating a tungsten layer, and more particularly a method for passivating a tungsten layer formed by physical vapour deposition (PVD). The present invention further relates to a method for the electrically conductive direct bonding of tungsten layers.

### PRIOR ART

Copper is normally used as a material for forming interconnections. However, the resistivity of copper increases significantly for thin films and fine interconnections. The conductivity of tungsten is then superior to that of copper.

Tungsten also has other advantages compared with copper. One advantage lies in the fact that tungsten is less contaminating than copper. Another advantage is related to the fact that tungsten has a melting point more than twice that of copper (3695 K for tungsten as against 1358 K for copper). As a result tungsten has better resistance to high temperature than copper, which is particularly advantageous for certain applications such as power applications. As a result also tungsten is less sensitive to electromigration than copper.

Moreover, technologies based on the stacking of chips or circuits on a plurality of levels, normally referred to by the term “3D integration”, make it possible to increase the integration density of components and to reduce the lengths of interconnections.

3D integration technologies require the use of assembly (or bonding) processes for forming the various levels. The various assembly steps may each correspond to an assembly of two semiconductor wafers (or semiconductor substrates), or to an assembly of a chip and a wafer, or to an assembly of chips. The transfer of a semiconductor layer or of a chip onto a previous stage may also require the use of thinning processes such as processes of the Smart Cut™ type.

Furthermore, 3D integration technologies require the formation of interconnections between the various levels. These interconnections are normally achieved by vias filled with conductive material, normally referred to by the acronym of English origin TSV (through silicon via) passing through the various stages of the semiconductor.

It is sought to use tungsten as the material making up the bonding layers and as the material providing the vertical conduction between the various levels. It is sought in particular to achieve direct bonding of two tungsten layers, that is to say without the addition of any material between the surfaces to be bonded.

For this purpose, one solution consists of effecting direct bonding of two layers of tungsten formed by chemical vapour deposition (CVD).

One drawback of such a method lies in the fact that it requires the formation of an attachment sublayer (seed layer) for germination in order to form the tungsten layer by CVD. This attachment sublayer, normally made from TiN, gives rise to a reduction in the conductivity of the assembly formed by the attachment sublayer and the tungsten layer.

Another drawback of such a method lies in the fact that the bonding energy is low at ambient temperature.

Another drawback of such a method lies in the fact that the formation of a tungsten layer by CVD is carried out at a temperature above 400° C. and requires densification at a temperature of around 600° C. of the tungsten layer formed. Such a method may therefore be difficult to use for bonding substrates comprising components before bonding.

Another solution consists of forming tungsten layers by a process of the PVD type.

Methods for the PVD deposition of tungsten do have several advantages compared with CVD deposition methods.

One advantage lies in the fact that the purity of a tungsten layer formed by PVD deposition is greater than that of a layer of tungsten formed by CVD deposition.

Another advantage lies in the fact that a PVD deposition of tungsten can be effected at ambient temperature or at low temperature, which is not the case with CVD deposition.

Another advantage lies in the fact that a PVD deposition of tungsten does not require the prior formation of an attachment sublayer. The result is better conductivity of a tungsten bonding layer formed by PVD compared with a bonding layer formed by CVD.

However, the known direct bonding methods at ambient temperature and atmospheric pressure of tungsten layers formed by PVD deposition do not make it possible to obtain sufficiently high bonding energies.

Furthermore, defects appear during subsequent heat treatments of the assembly, in particular for temperatures of around 300° C. to 500° C., which corresponds to the temperature ranges normally used during the fracture of a method of the Smart Cut™ type.

These problems of defectiveness and bonding energy are attributed to the presence of an unstable tungsten oxide at the bonding interface. During bonding, it is two layers of tungsten oxide that are put in contact, rather than two layers of tungsten.

The unstable tungsten oxide present at the bonding interface may have been formed during a chemical mechanical polishing (CMP) process carried out before the tungsten layers are put in contact in order to reduce their surface roughness. The tungsten oxide may also have been formed by thermal oxidation or by oxidation at ambient temperature, for example by exposure to air, of one or other or both tungsten layers. In all cases, an unstable native tungsten oxide layer is formed on each tungsten layer when the wafers are exposed to ambient air before and during bonding.

As illustrated by the phase diagram depicted in FIG. 1, the stoichiometry of tungsten oxide is complex. It may exist in numerous more or less stable phases with properties very different from one another. In particular, there exist changes in phase of tungsten oxide according to the initial phase for temperatures lying in the range of temperatures normally used for annealing heat treatments after bonding, these phase changes being accompanied by changes in volume. A tungsten oxide formed during a CMP process, for example under acidic pH conditions, may consist of an unstable mixture of WO₂ and WO₃.

Another solution for effecting direct bonding of two tungsten layers consists of using a bonding process under high vacuum normally designated in the art by the acronym of English origin SAB (surface activated bonding). Such a method consists of bombarding the surfaces to be bonded under high vacuum, for example by argon ions.

The ion bombardment causes an erosion of the surfaces and may, with thin layers (around 10 nm), degrade the conduction properties of the tungsten because of the amorphisation caused. The surfaces are next bonded, still under high vacuum.

One drawback of such a process lies in the fact that it is expensive and lengthy to implement. Furthermore, it requires control of particulate contamination. In addition, it is difficult to subsequently detach the two tungsten layers, which makes it difficult to recycle the assembled structures in the event of defects.

The problem is therefore posed of providing a method for the direct bonding of tungsten layers making it possible to obtain an increased bonding energy and reduced defectiveness.

The problem is also posed of providing a method for the direct bonding of tungsten layers, the bonding layers having reduced resistivity.

The problem is also posed of providing a method for the direct bonding of tungsten layers that is simple to implement and inexpensive.

### DISCLOSURE OF THE INVENTION

The present invention aims in particular to solve these problems.

The present invention relates first of all to a method for the formation and passivation of a tungsten layer, comprising the following steps performed successively:

a) depositing by PVD a layer of tungsten on a substrate; and

b) depositing by PVD a tungsten oxide passivation layer on the tungsten layer, by reactive sputtering in a plasma containing dioxygen, the tungsten oxide layer as deposited being amorphous and having a resistivity of between 5·10⁻² and 5·10⁻³ Ω·cm, the substrate being kept in an inert atmosphere between step a) and step b).

Inert atmosphere means an atmosphere that does not interact with the tungsten layer, whether in order to oxidise it or to reduce it.

According to one embodiment of the present invention, step a) of deposition of the tungsten layer and step b) of deposition of the tungsten oxide passivation layer are performed in the same PVD equipment without opening up to the air.

According to one embodiment of the present invention, during step b), dioxygen is introduced into the plasma used for the deposition of the tungsten layer during step a). Such a method is normally referred to by the English term “reactive sputtering”.

According to one embodiment of the present invention, during step b) the plasma contains argon and dioxygen.

According to one embodiment of the present invention, during step b) the equivalent flowrate of dioxygen in the plasma is between 5% and 20%.

According to one embodiment of the present invention, during step b) the flowrate of argon in the plasma is adapted so that the equivalent flowrate of dioxygen in the plasma remains between 5% and 20%.

According to one embodiment of the present invention, the tungsten oxide layer deposited during step b) has a “non-stoichiometric” chemical composition, intermediate between that of tungsten oxide of composition WO₃ and that of tungsten oxide of composition WO₄.

The thickness of the tungsten oxide layer deposited during step b) may be between 0.5 and 20 nm.

During step b), the deposition of the tungsten oxide layer may be achieved by reactive sputtering in RF mode. This makes it possible to avoid poisoning the tungsten target during the deposition.

The present invention also relates to a method for the direct bonding of a first substrate and a second substrate, comprising the following steps:

a′) for the first and second substrates, forming a tungsten layer covered with a tungsten oxide passivation layer by means of a method of the type described above; and

b′) putting the tungsten oxide passivation layer of the first substrate in contact with the tungsten oxide passivation layer of the second substrate.

Direct bonding means putting two sufficiently smooth and clean surfaces in contact in order to create adhesion between them, without the addition of any adhesive material between the two surfaces. Direct bonding is an assembly technique that can be carried out at ambient temperature and at atmospheric pressure.

Separating the substrates by traction (first mechanical action mode) then requires a certain amount of energy, referred to as the bonding energy.

The term substrate may designate either a wafer or a chip. A direct bonding method such as the one described above may apply not only to direct bonding between two substrates but also to direct bonding between a substrate and a chip or to direct bonding between two chips.

One advantage of a direct bonding method of the type described above lies in the fact that it makes it possible to obtain increased bonding energy. The bonding energy obtained by such a method is approximately three times greater than that obtained by a method not using a step of passivation of the tungsten layers after formation thereof by PVD and before bonding.

Another advantage of such a direct bonding method lies in the fact that it makes it possible to obtain reduced defectiveness. Such a method makes it possible to avoid the appearance of bonding defects during one or any heat treatments after step b′) of putting in contact. Bonding defects means defects that are not detectable by acoustic microscopy using a measuring head emitting acoustic waves at a frequency below approximately 30 MHz, which corresponds to a lateral resolution of around 10 μm. The acoustic microscopy technique is normally referred to by the acronym of English origin SAM (scanning acoustic microscopy).

Another advantage of such a method lies in the fact that the depositions of the layers of tungsten and tungsten oxide can be performed at ambient temperature. Such a method can therefore be used for assembling substrates already having components and/or already having undergone ion implantation, for example with a view to transfer by a method of the Smart Cut™ type.

Another advantage of such a method lies in the fact that the formation of the tungsten layers by PVD does not require the prior formation of attachment layers.

Another advantage of such a method lies in the fact that it makes it possible to obtain increased conductivity for the bonding layers formed from tungsten and tungsten oxide.

Another advantage of such a method lies in the fact that the tungsten oxide formed is stable at temperatures lying between ambient temperature and 1000° C. Such a method can therefore be used to form devices intended for power applications.

Another advantage of such a method lies in the fact that it is quick and inexpensive to implement. This is because the passivation of the tungsten layer is performed in the same PVD equipment as the deposition of the tungsten layer, just after the deposition of the tungsten layer.

The direct bonding method described above may also comprise a step c′) of annealing heat treatment after step b′) of putting in contact. The heat treatment may be performed at a temperature of between approximately 200° C. and the lowest melting point of the materials present (for example approximately 1400° C. for silicon), preferentially between approximately 200° and 500° C. Such an annealing heat treatment after bonding makes it possible to increase the bonding energy between the first and second substrates. It also makes it possible to increase the vertical conductivity of the assembly.

According to one embodiment of the present invention, during step a′) a tungsten layer is deposited in α phase.

According to one embodiment of the present invention, during step a′) a tungsten layer is deposited comprising at least partly tungsten in β phase; and during step c′) the heat treatment is performed at a temperature above approximately 100° C. in order to transform the tungsten in β phase into tungsten in α phase.

### BRIEF DESCRIPTION OF THE DRAWINGS

Other features and advantages of the invention will emerge more clearly from a reading of the following description and with reference to the accompanying drawings, given solely by way of illustration and in no way limitatively.

FIG. 1 is a phase diagram of tungsten oxide.

FIG. 2 is a diagram depicting successive steps of a method for direct bonding of tungsten layers according to the invention.

FIGS. 3A and 3B illustrate results of measurements of defectiveness by acoustic microscopy, after bonding and after successive heat treatments, for equivalent flowrates of dioxygen of 0%, 15% and 25% during the step of deposition of the tungsten oxide passivation layer.

FIG. 4 shows results of measuring the bonding energy by blade insertion according to the annealing heat treatment temperature after bonding, for equivalent flowrates of dioxygen of 0%, 15% and 25% during the step of deposition of the tungsten oxide passivation layer.

FIG. 5 is a view in cross section showing schematically an assembly of two substrates obtained by a method of direct bonding of tungsten layers according to the invention, through vias providing the vertical connections between the two substrates.

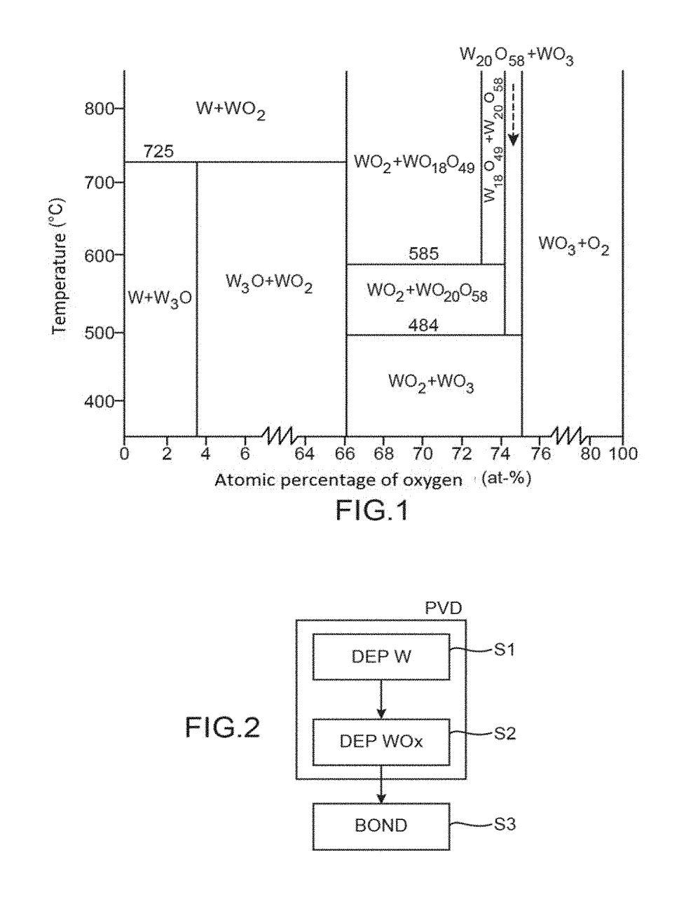

The various parts shown in the figures are not necessarily shown to a uniform scale, in order to make the figures more legible.

### DETAILED DISCLOSURE OF PARTICULAR EMBODIMENTS

The inventors propose to carry out an in situ passivation of a tungsten layer formed by physical vapour deposition (PVD). They propose to form a tungsten layer by PVD on a substrate and then, in the same PVD equipment and keeping the substrate under secondary vacuum, to form by reactive sputtering a layer of tungsten oxide WOₓ with controlled stoichiometry, stable under temperature, on the tungsten layer.

FIG. 2 is a diagram showing successive steps of a method for the formation and passivation of a tungsten layer by PVD.

A tungsten layer is deposited on a substrate, for example made from silicon, by PVD, for example by sputtering (step S1, “DEP W”).

The deposition of tungsten is carried out in a sputtering chamber of PVD equipment, under vacuum, for example under a high secondary vacuum at 10⁻⁷ torr.

The inert gas used in the working gas plasma is for example argon.

Optionally, the inert gas may be xenon. The target is a tungsten target.

The tungsten layer may be deposited in continuous mode (DC) or in alternating mode (RF).

The thickness of the tungsten layer deposited is for example between 2 and 50 nm.

Preferably, the tungsten layer is deposited in the α phase. According to an alternative, it may comprise tungsten in β phase; in this case, a subsequent heat treatment will advantageously be provided so as to transform the tungsten in β phase into tungsten in α phase. This heat treatment will for example be carried at a temperature above approximately 100° C.

By way of example of an order of magnitude of deposition conditions for the deposition of the tungsten layer:
the temperature is between 20° and 400° C.;
the partial pressure of argon is between 0.1 and 100 millitorr (1 torr corresponds to 133.322 Pa);
the power is between 10 and 5000 W;
the potential difference applied (biasing voltage) between the anode and the cathode of the deposition equipment is between −200 V and 200 V.

According to an example embodiment, the thickness of the tungsten layer deposited is around 10 mm and the conditions for deposition of the tungsten layer are as follows:
the temperature is around 30° C.;
the partial pressure of argon is around 1 millitorr;
the power is around 50 W;
the anode and the cathode are at the same potential.

Next a tungsten oxide layer with controlled stoichiometry is deposited on the tungsten layer in the same PVD equipment, by reactive sputtering (step S2, “DEP WOx”).

The deposition of the tungsten oxide layer is carried out just after the deposition of the tungsten layer, for example without taking the substrate out of the equipment and keeping the substrate under secondary vacuum. According to a variant, the substrate can be taken out of the equipment between the step of deposition of the tungsten layer and the step of deposition of the tungsten oxide layer, while keeping the substrate under inert atmosphere (neither oxidising nor reducing) between these two steps.

The inert gas used in the working-gas plasma is for example argon.

Optionally, the inert gas may be xenon. The reactive gas is dioxygen. The target is a tungsten target.

Advantageously, the deposition of the tungsten oxide layer is carried in the same sputtering chamber of the PVD equipment as that used for depositing the tungsten layer. In this case, dioxygen may be incorporated in the working-gas plasma used for depositing the tungsten layer by opening a dioxygen inlet valve in order to supply the working-gas plasma with dioxygen.

Controlling the partial pressure of dioxygen in the plasma makes it possible to form a layer of tungsten oxide WO_{X} with controlled stoichiometry, stable under temperature, on the tungsten layer. Such a tungsten oxide layer forms a passivation layer for the underlying tungsten layer. The stoichiometry obtained for the tungsten oxide layer will depend in particular on the partial pressure of dioxygen.

Forming a tungsten oxide passivation layer on the tungsten layer just after having formed the tungsten layer, keeping the substrate under inert atmosphere, for example in the same equipment under vacuum, makes it possible not to expose the tungsten layer to air and therefore to prevent an unstable native tungsten oxide layer forming on the tungsten layer.

The partial pressure of dioxygen in the plasma will for example be chosen so as to deposit an amorphous tungsten oxide layer with a resistivity of between approximately 5×10⁻² and 5×10⁻³ Ω·cm, for example around 5.1×10⁻³ Ω·cm. This corresponds to a tungsten oxide layer with a density of between approximately 6.7 and 6 g·cm⁻¹.

The equivalent flowrate of dioxygen in the working-gas plasma, in the case where the working-gas plasma contains argon as the inert gas and dioxygen as the reactive gas, is defined by the following equation: % O₂=D(O₂)/D(O₂)+D(Ar)), D(O₂) and D(Ar) designating respectively the flowrates of dioxygen and argon.

The dioxygen is for example incorporated in the plasma at an equivalent rate of between 5% and 20%.

A layer of tungsten oxide with a chemical composition WO₃₊ₓ with 0<x<1, that is to say a layer of WO₃ enriched with oxygen, is for example formed.

A layer of tungsten oxide with a chemical composition of between WO₃ and WO₄ is for example formed.

The phase of the tungsten oxide as deposited is amorphous. The stability of the tungsten oxide can be reinforced by an annealing heat treatment affording gradual recrystallisation of the tungsten oxide. The recrystallisation annealing of the tungsten oxide is for example carried out at a temperature above approximately 100° C., for example between approximately 100° C. and 500° C., for example between approximately 200° C. and 500° C.

Advantageously, the deposition of the tungsten oxide layer by reactive sputtering is carried in RF mode. This avoids poisoning the tungsten target.

The thickness of the tungsten oxide layer deposited is for example between 0.5 and 20 nm.

By way of example of an order of magnitude of deposition conditions for the deposition of the tungsten oxide layer:
the temperature is between 20° and 400° C.;
the flowrate of argon in the plasma is between 1 and 500 sccm (standard cubic centimetres per minute);
for a flowrate of argon of 50 sccm, the flowrate of dioxygen in the plasma is between 2.6 and 12.5 sccm.

According to an example embodiment, the thickness of the tungsten oxide layer deposited is around 5 nm and the conditions for deposition of the tungsten oxide layer are as follows:
the temperature is around 30° C.;
the flowrate of argon in the plasma is around 50 sccm;
the flowrate of dioxygen in the plasma is around 8.8 sccm.

A method for the formation and passivation of a tungsten layer such as the one described above can be used to form bonding layers with a view to carrying out electrically conductive direct bonding between two substrates.

In the following description, the term substrate may designate either a wafer or a chip. The electrically conductive direct bonding method described below may apply not only to direct bonding between two substrates but also to direct bonding between a substrate and a chip or to direct bonding between two chips.

Two substrates are first of all provided, each having a mean roughness (in RMS, root mean square) of less than approximately 1 nm over a surface of 20×20 μm², for example around 0.4 nm RMS.

In PVD equipment, steps S1 and S2 described above of depositing a layer of tungsten and then depositing a passivation layer of tungsten oxide on each of the two substrates are next carried out directly.

In this way a bonding layer formed by a tungsten layer covered by a tungsten oxide passivation layer is thus obtained on each substrate.

For each bonding layer, a person skilled in the art will in particular be able to choose the thickness of the tungsten layer and that of the tungsten oxide layer so as to obtain the required conductivity for the bonding layer, in particular according to the application sought.

The direct bonding of the two substrates is then proceeded with, by putting the bonding layers of each substrate in contact, and more precisely by putting in contact the tungsten oxide passivation layers of each substrate (step S3, “BOND”).

Step S3 of putting tungsten oxide layers of each substrate in contact is for example performed at ambient temperature and at atmospheric pressure, in ambient air.

Advantageously, an annealing heat treatment is then carried out after bonding. The annealing heat treatment after bonding is for example carried out at a temperature of between approximately 200° C. and the lowest melting point of the material present (for example approximately 1400° C. for silicon), preferably between approximately 200° and 500° C. Such annealing heat treatment after bonding increases the bonding energy. It also increases the vertical conductivity of the assembly.

In the case where the thermal budget is low for the annealing heat treatment after bonding, that is to say that it must for example be carried out at a temperature of less than approximately 100° C., a tungsten layer will preferably be deposited in its a phase during step S1, since this phase is more stable and less resistive.

In the case where the thermal budget is higher for the annealing heat treatment after bonding, that is to say it may for example be carried out at a temperature above approximately 100° C., it would be possible to deposit, during step S1, a tungsten layer in its a phase or in its β phase or it will be possible to deposit a tungsten layer comprising tungsten in α phase and tungsten in β phase, since tungsten in β phase will be transformed into tungsten in α phase during the heat treatment.

One advantage of the direct bonding method of the type described in relation to FIG. 2 lies in the fact that it makes it possible to obtain an increased bonding energy. The bonding energy obtained by such a method is approximately three times greater than that obtained by a method not using a step of passivation of the tungsten layers after formation thereof by PVD and before bonding.

Another advantage of such a direct bonding method lies in the fact that it makes it possible to obtain reduced defectiveness. Such a method makes it possible to avoid the appearance of defects during any heat treatment operation or operations after bonding.

Another advantage of such a method lies in the fact that the depositions of the tungsten and tungsten oxide layers can be carried out at ambient temperature or at a temperature below that of the methods of the prior art. Such a method can then be used for assembling substrates already having components.

Another advantage of such a method lies in the fact that the formation of the tungsten layers by PVD does not require the prior formation of attachment layers. Another advantage of such a method lies in the fact that it makes it possible to obtain increased conductivity for the bonding layers formed from tungsten and tungsten oxide.

Another advantage of such a method lies in the fact that the tungsten oxide formed is stable up to temperatures of approximately 1000° C. Such a method can therefore be used to form devices intended for power applications.

Another advantage of such a method lies in the fact that it is quick and inexpensive to implement. This is because the passivation of the tungsten layers is carried out in the same PVD equipment as the deposition of the tungsten layers, just after the deposition of the tungsten layers.

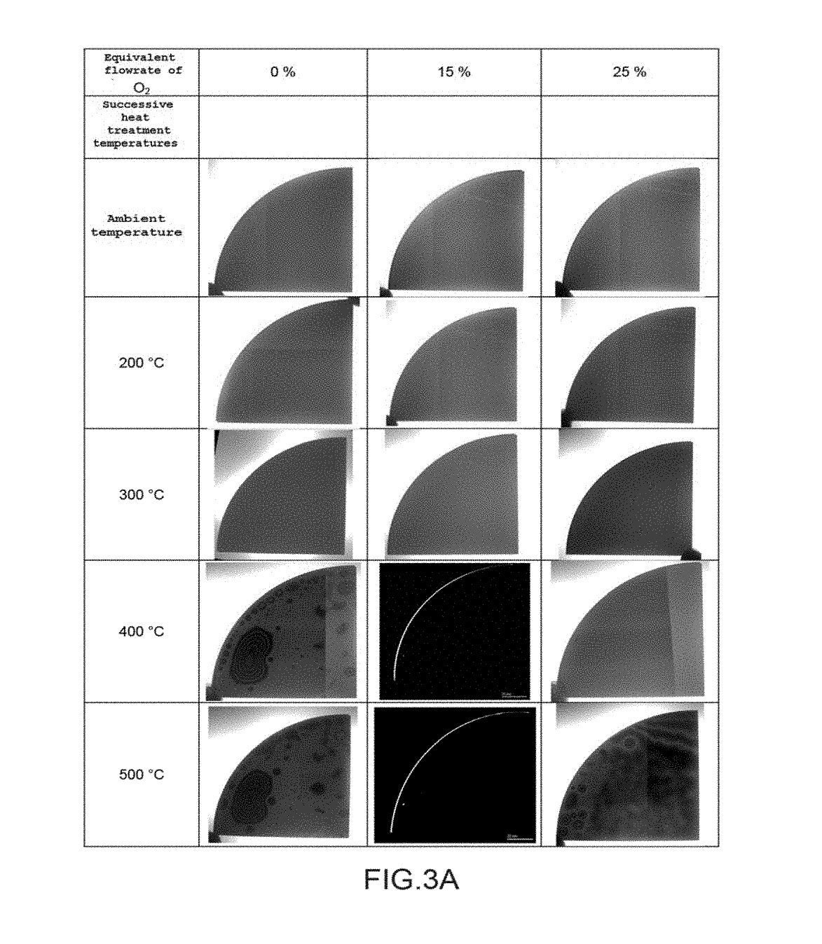

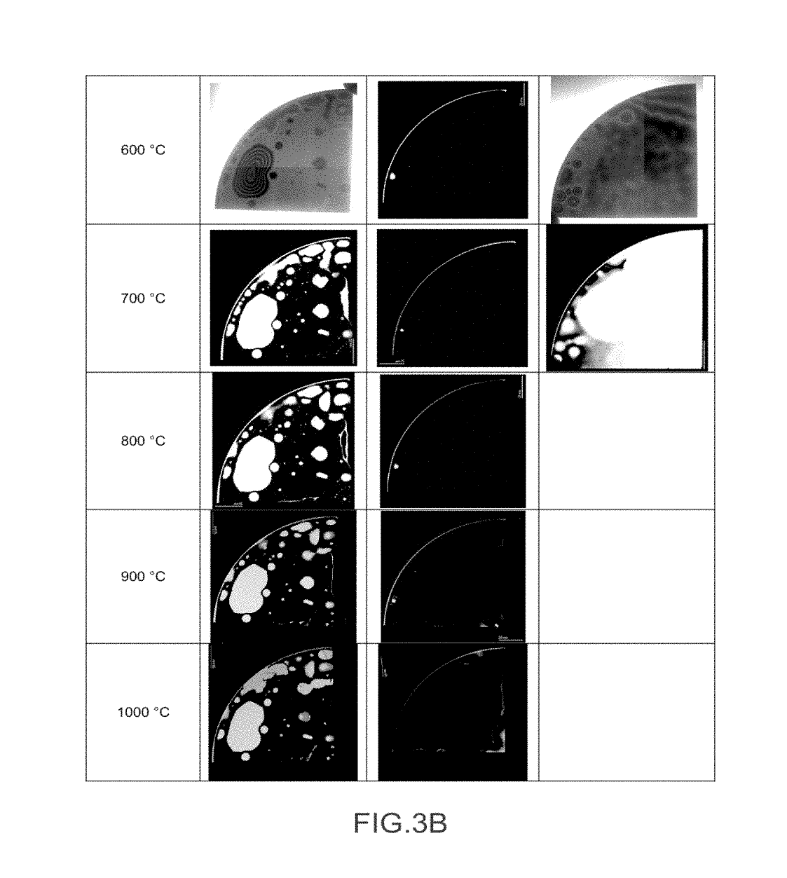

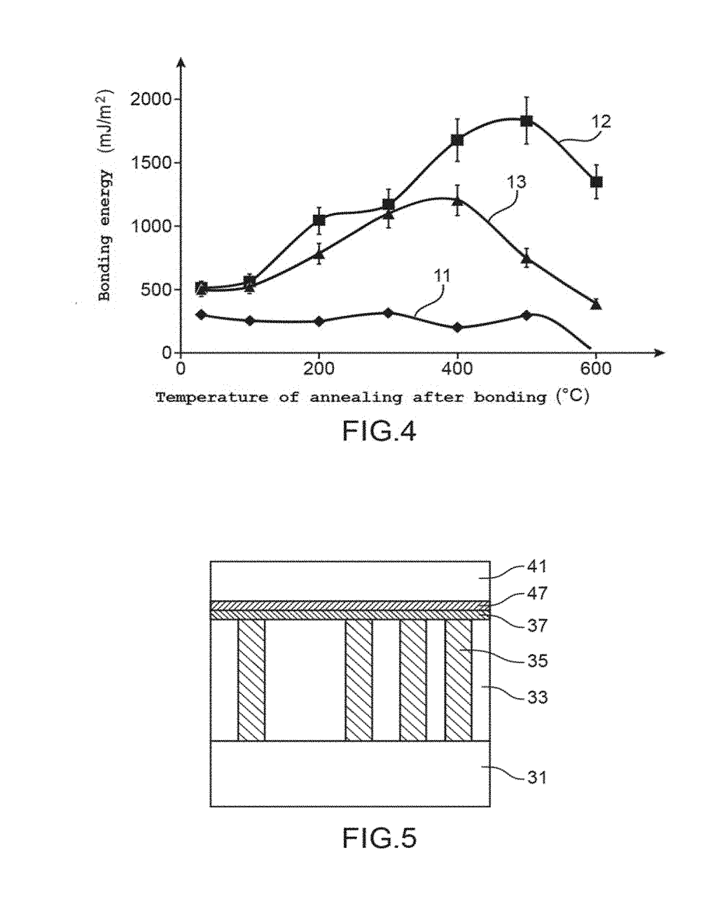

FIGS. 3A-3B and 4 show results of measurements of defectiveness and bonding energy carried out on assemblies of substrates obtained by a method such as the one described in relation to FIG. 2.

The substrates are made from silicon. On each substrate, the bonding layer, formed by a tungsten layer with a thickness of around 10 nm covered with a tungsten oxide layer with a thickness of around 5 nm, was formed before the bonding.

Steps S1 of deposition of the tungsten layer and S2 of deposition of the tungsten oxide layer were carried out in the same sputtering chamber of PVD equipment of make Alliance Concept CT200, at a high secondary vacuum of around 10⁻⁷ torr.

The deposition of the tungsten layer and the deposition of the tungsten oxide layer were carried out in a working-gas plasma containing argon as the inert gas. The deposition of the tungsten oxide layer was carried out in RF mode. The deposition of the tungsten layer may be carried in RF or DC mode.

The deposition of the tungsten oxide layer was carried out with a flowrate of argon of around 50 sccm, with the incorporation of dioxygen as the reactive gas in the working-gas plasma.

The bonding was carried out manually, in ambient air and at ambient temperature. It was implemented quickly after the substrates were put in the open air after steps S1 of deposition of the tungsten layer and S2 of deposition of the tungsten oxide passivation layer. The length of time waited between the end of step S2 of deposition of the tungsten oxide passivation layer and the start of the bonding step is for example less than or equal or 30 minutes.

The measurements were made after the bonding and after various heat treatments. The heat treatments were carried out in ambient air.

FIGS. 3A and 3B illustrate results of measurements of defectiveness carried out by acoustic microscopy, after the bonding and after successive heat treatments. The measurements were made for equivalent flowrates of dioxygen of 0%, 15% and 25% in the working-gas plasma.

For an equivalent flowrate of dioxygen of 0%, that is to say in the case where no tungsten oxide passivation layer is formed, defects appear as from a temperature above 300° C.

For an equivalent flowrate of dioxygen of around 25%, defects appear as from a temperature above 400° C. A separation of the two substrates is observed at a temperature above 700° C.

For an equivalent flowrate of dioxygen of around 15%, only a particulate edge-of-plate defect appears at a temperature of around 400° C. and is resorbed at a temperature of around 1000° C. Apart from this particulate edge-of-plate defect, no defect appears after the various successive heat treatments.

These results confirm that the formation of a tungsten oxide passivation layer with a well-chosen stoichiometry on each tungsten layer, by a method of the type described in relation to FIG. 2, makes it possible to minimise the appearance of defects during any heat treatments carried out after bonding.

FIG. 4 shows results of measurement of the bonding energy as a function of the annealing heat treatment temperature after bonding. The curves 11, 12 and 13 correspond respectively to equivalent flowrates of dioxygen in the working-gas plasma of 0%, 15% and 25%.

The bonding energies were evaluated by the blade insertion method, in an anhydrous atmosphere, with an uncertainty of 10%.

For an equivalent flowrate of dioxygen of 0%, it is noted that the bonding energy is low at ambient temperature and remains low and substantially constant as a function of the annealing temperature after bonding. In the case where no tungsten oxide passivation layer is formed, an annealing heat treatment after bonding does not make it possible to increase the bonding energy.

For equivalent flowrates of dioxygen of 15% and 25%, the bonding energy at ambient temperature is substantially twice as great as that obtained with an equivalent flowrate of dioxygen of 0%. The bonding energies for equivalent O₂ flowrates of 15% and 25% are substantially equal. These results confirm that the formation of a tungsten oxide passivation layer makes it possible to increase the bonding energy at ambient temperature.

For equivalent flowrates of dioxygen of 15% and 25%, these results confirm that an annealing heat treatment after bonding makes it possible to significantly increase the bonding energy.

For an equivalent flowrate of O₂ of 25%, a reduction in the bonding energy is however observed for annealing temperatures after bonding above approximately 400° C. This drop in the bonding energy may be attributed to the appearance of defects (FIG. 3A). For annealing temperatures after bonding above approximately 400° C., the bonding energy for an equivalent flowrate of O₂ of 15% is appreciably greater than that obtained with an equivalent flowrate of O₂ of 25%.

For an equivalent flowrate of O₂ of 15%, a slight reduction in the bonding energy is observed for annealing temperatures above approximately 500° C.

However, the bonding energy for such an equivalent flowrate of O₂ and for annealing temperatures above 500° C. remains appreciably greater than the bonding energy at ambient temperature for this same equivalent flowrate of O₂.

These results confirm that the formation of a tungsten oxide passivation layer with a well-chosen stoichiometry on each tungsten layer, by a method of the type described in relation to FIG. 2, makes it possible to increase the bonding energy at ambient temperature. An annealing heat treatment after bonding also makes it possible to significantly increase the bonding energy compared with the bonding energy obtained at ambient temperature.

A person skilled in the art would be able to choose the equivalent flowrate of dioxygen in the working-gas plasma and the annealing temperature after bonding according to the bonding energy required.

FIG. 5 is a view in cross section showing schematically an example of an assembly of two substrates that can be obtained by a direct bonding method such as the one described in relation to FIG. 2.

A dielectric layer 33 has been formed on a semiconductor substrate 31.

Through vias 35 filled with tungsten have been formed through the dielectric layer 33. A bonding layer 37, formed by a tungsten layer covered with a tungsten oxide passivation layer, has been formed on the dielectric layer 33.

A bonding layer 47, formed by a tungsten layer covered with a tungsten oxide passivation layer, has been formed on another semiconductor substrate 41.

The tungsten oxide passivation layers of each bonding layer 37, 47 have been put in contact in order to effect direct bonding of the two substrates.

In this way an assembly of two semiconductor substrates 31 and 41 is obtained, the bonding layers 37 and 47 disposed between the two substrates being electrically conductive. The through vias 35 are intended to provide the vertical connections between the two substrates.

Because a method of the type described in relation to FIG. 2 makes it possible to minimise the appearance of defects during heat treatments carried out after bonding, it is possible for example to proceed after the bonding with a thinning of the substrate 41 by a method of the Smart Cut™ type. For this purpose, it is possible to form a weakened zone in the substrate 41 before forming the bonding layer 47. After bonding, it is then possible to detach a part of the substrate 41 of the assembly, by fracture along the weakened zone. The fracture may be obtained by heat treatment, for example carried out at a temperature of between approximately 300° C. and approximately 500° C.

1-12. (canceled)

13. A method for the formation and passivation of a tungsten layer, comprising, performed successively:
a) depositing by PVD a layer of tungsten on a substrate; and
b) depositing by PVD a tungsten oxide passivation layer on the tungsten layer, by reactive sputtering in a plasma containing dioxygen, the tungsten oxide layer as deposited being amorphous and having a resistivity of between 5·10⁻² and 5·10⁻³ Ω·m, the substrate being kept in an inert atmosphere between a) and b).

14. A method according to claim 13, wherein a) depositing the tungsten layer and b) depositing the tungsten oxide passivation layer are performed in same PVD equipment without bringing into open air.

15. A method according to claim 13, wherein, during b), dioxygen is introduced into the plasma used for deposition of the tungsten layer during a).

16. A method according to claim 13, wherein, during b), the plasma contains argon and dioxygen.

17. A method according to claim 16, wherein, during b), equivalent flowrate of dioxygen in the plasma is between 5% and 20%.

18. A method according to claim 13, wherein the layer of tungsten oxide deposited during b) has a chemical composition intermediate between that of tungsten oxide of composition WO₃ and that of tungsten oxide of composition WO₄.

19. A method according to claim 13, wherein the thickness of the layer of tungsten oxide deposited during b) is between 0.5 and 20 nm.

20. A method according to claim 13, wherein, during b), deposition of the tungsten oxide layer is carried out by reactive sputtering in RF mode.

21. A method for direct bonding of a first substrate and a second substrate, comprising:
a′) for the first and second substrates, forming a tungsten layer covered with a tungsten oxide passivation layer by a method according to claim 13; and
b′) putting the tungsten oxide passivation layer of the first substrate in contact with the tungsten oxide passivation layer of the second substrate.

22. A method according to claim 21, further comprising c′) heat treatment after b′) of putting in contact, to increase bonding energy between the first and second substrates.

23. A method according to claim 21, wherein, during a′), a layer of tungsten in α phase is deposited.

24. A method according to claim 22, wherein:
during a′), a tungsten layer comprising at least partly tungsten in β phase is deposited;
and, during c′), the heat treatment is carried out at a temperature above approximately 100° C. to transform the tungsten in β phase into tungsten in α phase.
